(19) United States
(12) Patent Application Publication
(10) Pub. No.: US 2026/0304800 A1
(43) Pub. Date: Oct. 1, 2026

(54) SEMICONDUCTOR DEVICE

(71) Applicant: SK hynix Inc., Gyeonggi-do (KR)

(72) Inventors: Yu Jin KIM, Gyeonggi-do (KR); Se Hun KANG, Gyeonggi-do (KR); Ki Vin IM, Gyeonggi-do (KR); Nam Gue LEE, Gyeonggi-do (KR); Sung Hyun CHO, Gyeonggi-do (KR)

(21) Appl. No.: 19/337,928

(22) Filed: Sep. 24, 2025

(30) Foreign Application Priority Data
Mar. 27, 2025 (KR) 10-2025-0039340

(51) Int. Cl. H10D 1/68; H10B 12/00; H10B 53/20; H10B 53/30; H10B 53/10

(52) U.S. Cl. CPC H10D 1/68; H10B 12/315; H10B 12/34; H10B 53/20; H10B 53/30; H10B 12/033; H10B 53/10; H10D 1/716

(57) ABSTRACT

A semiconductor device according to embodiments of the present disclosure includes a first electrode and a second electrode, a ferroelectric layer disposed between the first electrode and the second electrode, a first polarization control layer disposed between the first electrode and the ferroelectric layer, and a second polarization control layer disposed between the second electrode and the ferroelectric layer. An oxygen area density of the ferroelectric layer is between an oxygen area density of the first polarization control layer and an oxygen area density of the second polarization control layer.

### CROSS-REFERENCES TO RELATED APPLICATION

The present application claims priority under 35 U.S.C. 119(a) to Korean patent application number 10-2025-0039340 filed on Mar. 27, 2025, which is incorporated herein by reference in its entirety.

### BACKGROUND

### 1. Technical Field

Embodiments of the present disclosure relate to a semiconductor device.

### 2. Related Art

Due to characteristics such as miniaturization, multifunctionality, and/or low manufacturing cost, semiconductor devices are gaining attention as important components in the electronics industry. As the electronics industry advances significantly, semiconductor devices are becoming increasingly highly integrated. As semiconductor devices become more highly integrated, the number of unit elements such as capacitors arranged within the semiconductor devices increases. Maintaining the characteristics of such unit elements in a stable manner faces technical challenges.

### SUMMARY

According to embodiments of the present disclosure, a semiconductor device capable of minimizing degradation of the semiconductor device caused by repetitive switching operations may be provided.

The objects of the embodiments of the present disclosure are not limited to those mentioned herein, and other objects not explicitly described may be clearly understood by those skilled in the art from the following description.

Embodiments of the present disclosure may provide a semiconductor device including a first electrode and a second electrode, a ferroelectric layer disposed between the first electrode and the second electrode, a first polarization control layer disposed between the first electrode and the ferroelectric layer, and a second polarization control layer disposed between the second electrode and the ferroelectric layer. An oxygen area density of the ferroelectric layer is between an oxygen area density of the first polarization control layer and an oxygen area density of the second polarization control layer.

Embodiments of the present disclosure may provide a semiconductor device including a first electrode and a second electrode; a ferroelectric layer disposed between the first electrode and the second electrode and including a first ferroelectric layer and a second ferroelectric layer spaced apart from each other; a domain separation layer disposed between the first ferroelectric layer and the second ferroelectric layer; a first polarization control layer disposed between the first electrode and the first ferroelectric layer; and a second polarization control layer disposed between the second electrode and the second ferroelectric layer. Each of the first polarization control layer and the second polarization control layer has an oxygen area density different from an oxygen area density of the first ferroelectric layer and an oxygen area density of the second ferroelectric layer.

Embodiments of the present disclosure may provide a semiconductor device comprising a substrate including an active region; a lower electrode contact plug connected to the active region; a lower electrode connected to the lower electrode contact plug; an upper electrode disposed over the lower electrode; a ferroelectric layer disposed between the lower electrode and the upper electrode; a first polarization control layer disposed between the lower electrode and the ferroelectric layer; and a second polarization control layer disposed between the upper electrode and the ferroelectric layer. An oxygen area density of the ferroelectric layer is between an oxygen area density of the first polarization control layer and an oxygen area density of the second polarization control layer.

According to embodiments of the present disclosure, a semiconductor device can minimize the degradation caused by repeated switching operations.

The effects of the embodiments of the present disclosure are not limited to those mentioned above, and other effects not explicitly described may also be clearly understood by those skilled in the art from the claims.

### BRIEF DESCRIPTION OF THE DRAWINGS

The present disclosure will be more fully understood from the detailed description and accompanying drawings provided below, which are provided solely for explanation purposes and do not limit the scope of the present disclosure.

FIG. 1 is a diagram illustrating an example of a cross-sectional structure of a semiconductor device according to embodiments of the present disclosure.

FIG. 2 is a diagram schematically illustrating polarization behavior of the semiconductor device shown in FIG. 1.

FIG. 3 is a diagram illustrating another example of a cross-sectional structure of a semiconductor device according to embodiments of the present disclosure.

FIG. 4 is a diagram schematically illustrating polarization behavior of the semiconductor device shown in FIG. 3.

FIG. 5 is a diagram illustrating another example of a cross-sectional structure of a semiconductor device according to embodiments of the present disclosure.

FIG. 6 is a diagram illustrating another example of a cross-sectional structure of a semiconductor device according to embodiments of the present disclosure.

FIG. 7 is a diagram schematically illustrating polarization behavior of the semiconductor device shown in FIG. 6.

FIG. 8 is a diagram illustrating another example of a cross-sectional structure of a semiconductor device according to embodiments of the present disclosure.

FIG. 9 is a diagram roughly illustrating polarization behavior of the semiconductor device shown in FIG. 8.

FIG. 10 is a diagram illustrating another example of a cross-sectional structure of a semiconductor device according to embodiments of the present disclosure.

FIGS. 11 and 12 are diagrams schematically illustrating polarization behavior of the semiconductor device shown in FIG. 10.

FIG. 13 is a diagram illustrating another example of a cross-sectional structure of a semiconductor device according to embodiments of the present disclosure.

FIG. 14 is a diagram illustrating an example of a planar structure of a semiconductor device according to embodiments of the present disclosure.

FIG. 15 is a diagram illustrating examples of cross-sectional structures taken along lines I–I′ and II–II′ of FIG. 14.

FIG. 16 is a diagram showing an enlarged view of a portion 10 of FIG. 15.

FIGS. 17 to 23 are diagrams illustrating examples of a method for manufacturing a semiconductor device according to embodiments of the present disclosure.

### DETAILED DESCRIPTION

Hereinafter, embodiments of the disclosure are described in detail with reference to the accompanying drawings. In assigning reference numerals to components in each drawing, identical components may be assigned the same reference numerals even when shown in different drawings. If details of known art or functions are deemed to obscure the subject matter of the disclosure, such details may be omitted. As used herein, terms such as “comprises,” “has,” or “is composed of” in relation to a component may permit the inclusion of additional components unless terms like “only” are explicitly used. Additionally, unless the context clearly indicates otherwise, expressions in the singular, such as “a,” “an,” and “the” are intended to include their plural forms.

Such denotations as “first," "second," "A," "B," "(a)," and "(b)" may be used to describe components of the disclosure. These denotations are intended merely to distinguish one component from another, and are not intended to limit the nature, order, sequence, or number of the components.

Regarding the description of positional relationships between components, when two or more components are described as being "connected," "coupled," or "linked," it should be understood that they may be directly "connected," "coupled," or "linked," or may have an intervening component. Here, the intervening component may be included in one or more of the two or more components that are “connected,” “coupled,” or “linked” to each other.

When terms such as “after,” “next to,” “subsequent to” or “before,” are used to describe the temporal or sequential relationships between components, operation methods, or fabrication methods, they may also encompass a non-continuous case unless terms like “immediately” or “directly” are explicitly used.

When a component is associated with a value or its corresponding information (e.g., level), such value or information may be interpreted to include tolerances arising due to various factors (e.g., process variations, internal or external impacts, or noise), even without explicit separate descriptions.

Hereinafter, various embodiments of the disclosure are described in detail with reference to the accompanying drawings.

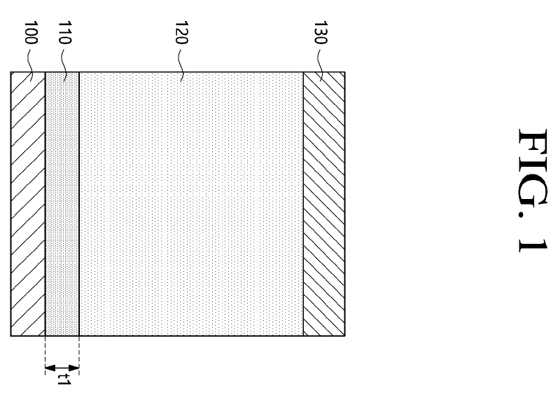

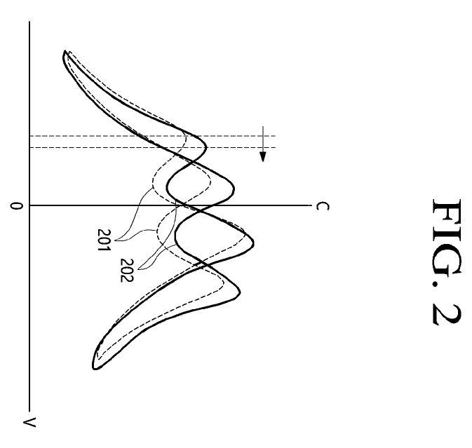

FIG. 1 is a diagram illustrating an example of a cross-sectional structure of a semiconductor device according to embodiments of the present disclosure. FIG. 2 is a diagram schematically illustrating polarization behavior of the semiconductor device shown in FIG. 1.

Referring to FIG. 1, a semiconductor device according to embodiments of the present disclosure includes a first electrode 100, a first polarization control layer 110, a ferroelectric layer 120, and a second electrode 130. The semiconductor device may further include additional components beyond those mentioned above, and is not limited to only the illustrated components.

The first electrode 100 and the second electrode 130 are disposed apart from each other. The ferroelectric layer 120 is disposed between the first electrode 100 and the second electrode 130. The first polarization control layer 110 is disposed between the first electrode 100 and the ferroelectric layer 120.

The first electrode 100 may include a conductive material such as metal, metal nitride, metal silicide, polysilicon, conductive carbon, or a combination thereof. For example, the first electrode 100 may include titanium nitride.

The first polarization control layer 110 is disposed on the first electrode 100. The first polarization control layer 110 may include a material having an oxygen area density different from that of the ferroelectric layer 120. The oxygen area density may refer to the concentration of oxygen atoms located on the surface of the material.

In one embodiment, the first polarization control layer 110 may include a material having an oxygen area density greater than that of the ferroelectric layer 120. Hereinafter, a material having an oxygen area density greater than that of the ferroelectric layer 120 may be referred to as an N-type material. For example, when the ferroelectric layer 120 includes hafnium oxide, zirconium oxide, or a combination thereof, the N-type material may include magnesium oxide, silicon oxide, germanium oxide, yttrium oxide, lutetium oxide, lanthanum oxide, strontium oxide, niobium oxide, or a combination thereof.

Alternatively, in another embodiment, the first polarization control layer 110 may include a material having an oxygen area density less than that of the ferroelectric layer 120. Hereinafter, a material having an oxygen area density less than that of the ferroelectric layer 120 may be referred to as a P-type material. For example, when the ferroelectric layer 120 includes hafnium oxide, zirconium oxide, or a combination thereof, the P-type material may include titanium oxide, aluminum oxide, or a combination thereof. The above-described N-type and P-type materials are merely examples, and the types of N-type and P-type materials are not necessarily limited thereto.

In one embodiment, the thickness t1 of the first polarization control layer 110 may be in a range from 1 angstrom to 5 angstroms. Since the thickness t1 of the first polarization control layer 110 cannot be smaller than the thickness of a monolayer, it should be at least 1 angstrom. In addition, if the thickness t1 of the first polarization control layer 110 is equal to or greater than 5 angstroms, the dielectric constant of the semiconductor device may be reduced, and thus the thickness t1 should be less than 5 angstroms.

In one embodiment, the first polarization control layer 110 may control the direction and magnitude of polarization of the ferroelectric layer 120. For example, when the first polarization control layer 110 includes an N-type material, an interface dipole may be formed at the interface between the first polarization control layer 110 and the ferroelectric layer 120. In this case, the direction of the interface dipole may be from the first polarization control layer 110 toward the ferroelectric layer 120. The interface dipole formed between the first polarization control layer 110 and the ferroelectric layer 120 may generate a built-in potential in the ferroelectric layer 120. The built-in potential may be directed from the ferroelectric layer 120 toward the first polarization control layer 110. Due to the built-in potential, the direction and magnitude of polarization in the ferroelectric layer 120 may be aligned in the direction of the built-in potential. As the difference in oxygen area density between the material included in the first polarization control layer 110 and the ferroelectric layer 120 increases, the variation in the direction and magnitude of polarization of the ferroelectric layer 120 may become more significant.

Alternatively, for example, when the first polarization control layer 110 includes a P-type material, an interface dipole may be formed at the interface between the first polarization control layer 110 and the ferroelectric layer 120. In this instance, the direction of the interface dipole may be from the ferroelectric layer 120 toward the first polarization control layer 110. The interface dipole formed between the first polarization control layer 110 and the ferroelectric layer 120 may generate a built-in potential in the ferroelectric layer 120. The built-in potential may be directed from the first polarization control layer 110 toward the ferroelectric layer 120. Due to the built-in potential, the direction and magnitude of polarization in the ferroelectric layer 120 may be aligned in the direction of the built-in potential. As the difference in oxygen area density between the material included in the first polarization control layer 110 and the ferroelectric layer 120 increases, the variation in the direction and magnitude of polarization of the ferroelectric layer 120 may become more significant.

The ferroelectric layer 120 is disposed on the first polarization control layer 110. The ferroelectric layer 120 may include a material having ferroelectricity. For example, the ferroelectric layer 120 may include hafnium oxide, zirconium oxide, hafnium-zirconium oxide, or a combination thereof.

The second electrode 130 is disposed on the ferroelectric layer 120. The second electrode 130 may include a conductive material such as metal, metal nitride, metal silicide, polysilicon, conductive carbon, or a combination thereof. For example, the second electrode 130 may include titanium nitride.

FIG. 2 is a diagram illustrating the polarization change of the ferroelectric layer 120 when the first polarization control layer 110 includes an N-type material. Referring to FIG. 2, the capacitance C of the ferroelectric layer 120 may vary depending on an external voltage V applied to the ferroelectric layer 120.

Referring to FIGS. 1 and 2, in a case where the first polarization control layer 110 is not provided, the polarization behavior 201 (hereinafter, first polarization behavior) of the ferroelectric layer 120 may be different from the polarization behavior 202 (hereinafter, second polarization behavior) of the ferroelectric layer 120 when the first polarization control layer 110 including an N-type material is disposed between the ferroelectric layer 120 and the first electrode 100.

For example, the magnitude of the voltage required to reverse polarization in the second polarization behavior 202 may differ from that required to reverse polarization in the first polarization behavior 201. Specifically, the magnitude of the voltage required to reverse polarization in the second polarization behavior 202 may be smaller than that required to reverse polarization in the first polarization behavior 201. Referring to FIG. 2, the second polarization behavior 202 may be shifted to the right relative to the first polarization behavior 201.

Alternatively, for example, when the first polarization control layer 110 includes a P-type material, the second polarization behavior 202 may be shifted to the left compared to the first polarization behavior 201, which is opposite to what is shown in FIG. 2.

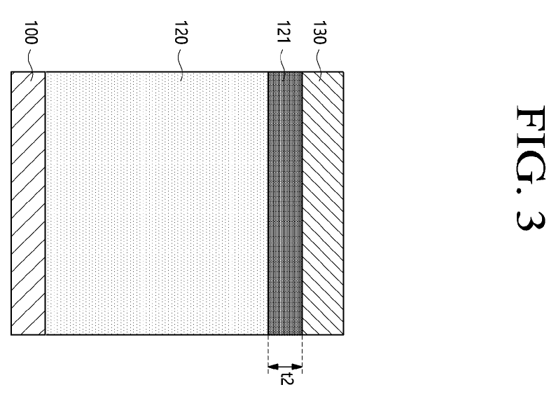

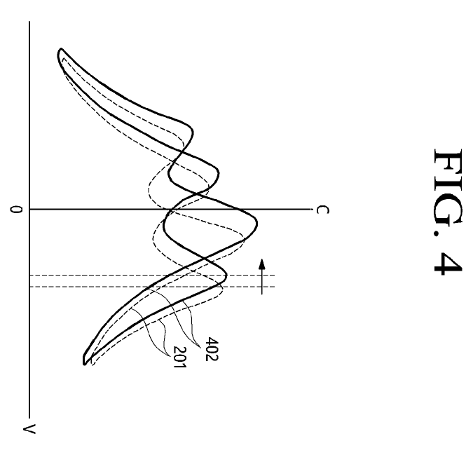

FIG. 3 is a diagram illustrating another example of a cross-sectional structure of a semiconductor device according to embodiments of the present disclosure. FIG. 4 is a diagram schematically illustrating polarization behavior of the semiconductor device shown in FIG. 3.

Referring to FIG. 3, the semiconductor device includes a first electrode 100, a ferroelectric layer 120, a second polarization control layer 121, and a second electrode 130. The ferroelectric layer 120 is disposed between the first electrode 100 and the second electrode 130. The second polarization control layer 121 is disposed between the ferroelectric layer 120 and the second electrode 130. The first electrode 100, second electrode 130, and ferroelectric layer 120 may be substantially the same as those described with reference to FIG. 1.

The second polarization control layer 121 may include a material having an oxygen area density different from that of the ferroelectric layer 120.

In one embodiment, the second polarization control layer 121 may include an N-type material. For example, when the ferroelectric layer 120 includes hafnium oxide, zirconium oxide, or a combination thereof, the second polarization control layer 121 may include magnesium oxide, silicon oxide, germanium oxide, yttrium oxide, lutetium oxide, lanthanum oxide, strontium oxide, niobium oxide, or a combination thereof.

Alternatively, in another embodiment, the second polarization control layer 121 may include a P-type material. For example, when the ferroelectric layer 120 includes hafnium oxide, zirconium oxide, or a combination thereof, the second polarization control layer 121 may include titanium oxide, aluminum oxide, or a combination thereof.

In one embodiment, the thickness t2 of the second polarization control layer 121 may be in a range from 1 angstrom to 5 angstroms. Since the thickness t2 of the second polarization control layer 121 cannot be smaller than the thickness of a monolayer, it should be at least 1 angstrom. Additionally, if the thickness t2 is equal to or greater than 5 angstroms, the dielectric constant of the semiconductor device may be reduced, and thus the thickness t2 should be less than 5 angstroms.

In one embodiment, the second polarization control layer 121 may control the direction and magnitude of polarization of the ferroelectric layer 120. For example, when the second polarization control layer 121 includes an N-type material, an interface dipole may be formed at the interface between the second polarization control layer 121 and the ferroelectric layer 120. In this case, the direction of the interface dipole may be from the second polarization control layer 121 toward the ferroelectric layer 120. The interface dipole formed between the second polarization control layer 121 and the ferroelectric layer 120 may generate a built-in potential in the ferroelectric layer 120. The built-in potential may be directed from the ferroelectric layer 120 toward the second polarization control layer 121. Due to the built-in potential, the direction and magnitude of polarization in the ferroelectric layer 120 may be aligned in the direction of the built-in potential. As the difference in oxygen area density between the material included in the second polarization control layer 121 and the ferroelectric layer 120 increases, the variation in the direction and magnitude of polarization in the ferroelectric layer 120 may become more significant.

Alternatively, for example, when the second polarization control layer 121 includes a P-type material, an interface dipole may be formed at the interface between the second polarization control layer 121 and the ferroelectric layer 120. In this case, the direction of the interface dipole may be from the ferroelectric layer 120 toward the second polarization control layer 121. The interface dipole formed between the second polarization control layer 121 and the ferroelectric layer 120 may generate a built-in potential in the ferroelectric layer 120. The built-in potential may be directed from the second polarization control layer 121 toward the ferroelectric layer 120. Due to the built-in potential, the direction and magnitude of polarization in the ferroelectric layer 120 may be aligned in the direction of the built-in potential. As the difference in oxygen area density between the material included in the second polarization control layer 121 and the ferroelectric layer 120 increases, the variation in the direction and magnitude of polarization in the ferroelectric layer 120 may become more significant.

FIG. 4 is a diagram illustrating the polarization change of the ferroelectric layer 120 when the second polarization control layer 121 includes an N-type material. Referring to FIG. 2, the capacitance C of the ferroelectric layer 120 may vary depending on the external voltage V applied to the ferroelectric layer 120.

The polarization behavior 402 (hereinafter, third polarization behavior) of the ferroelectric layer 120 when the second polarization control layer 121 including an N-type material is disposed between the ferroelectric layer 120 and the second electrode 130 may be different from the first polarization behavior 201.

For example, the magnitude of the voltage required to reverse polarization in the third polarization behavior 402 may be smaller than that required to reverse polarization in the first polarization behavior 201. Referring to FIG. 4, the third polarization behavior 402 may be shifted to the left relative to the first polarization behavior 201.

Alternatively, for example, when the second polarization control layer 121 includes a P-type material, the third polarization behavior 402 may be shifted to the right relative to the first polarization behavior 201, which is opposite to that shown in FIG. 4.

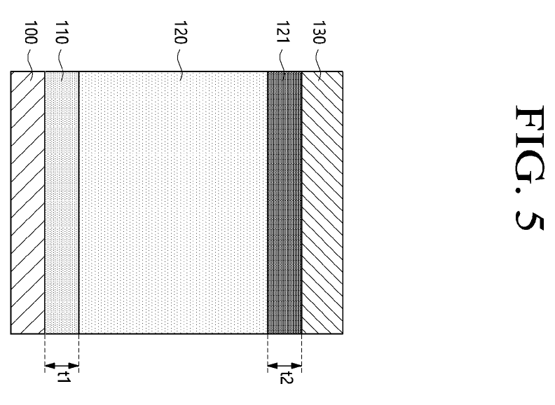

FIG. 5 is a diagram illustrating another example of a cross-sectional structure of a semiconductor device according to embodiments of the present disclosure.

Referring to FIG. 5, the semiconductor device includes a first electrode 100, a first polarization control layer 110, a ferroelectric layer 120, a second polarization control layer 121, and a second electrode 130. The first polarization control layer 110 may be disposed between the first electrode 100 and the ferroelectric layer 120, and the second polarization control layer 121 may be disposed between the second electrode 130 and the ferroelectric layer 120. The first electrode 100, second electrode 130, and ferroelectric layer 120 may be substantially the same as those described with reference to FIG. 1.

The first and second polarization control layers 110 and 121 may include materials having oxygen area densities different from that of the ferroelectric layer 120.

In one embodiment, the first polarization control layer 110 may include an N-type material, and the second polarization control layer 121 may include a P-type material. For example, when the ferroelectric layer 120 includes hafnium oxide, zirconium oxide, or a combination thereof, the first polarization control layer 110 may include magnesium oxide, silicon oxide, germanium oxide, yttrium oxide, lutetium oxide, lanthanum oxide, strontium oxide, niobium oxide, or a combination thereof, and the second polarization control layer 121 may include titanium oxide, aluminum oxide, or a combination thereof. In other words, the oxygen area density of the ferroelectric layer 120 may be greater than that of the second polarization control layer 121 and less than that of the first polarization control layer 110.

Alternatively, in another embodiment, the first polarization control layer 110 may include a P-type material, and the second polarization control layer 121 may include an N-type material. For example, when the ferroelectric layer 120 includes hafnium oxide, zirconium oxide, or a combination thereof, the first polarization control layer 110 may include titanium oxide, aluminum oxide, or a combination thereof, and the second polarization control layer 121 may include magnesium oxide, silicon oxide, germanium oxide, yttrium oxide, lutetium oxide, lanthanum oxide, strontium oxide, niobium oxide, or a combination thereof. In other words, the oxygen area density of the ferroelectric layer 120 may be greater than that of the first polarization control layer 110 and less than that of the second polarization control layer 121.

In one embodiment, the thickness t1 of the first polarization control layer 110 and the thickness t2 of the second polarization control layer 121 may be in a range from 1 angstrom to 5 angstroms.

In one embodiment, the first and second polarization control layers 110 and 121 may control the direction and magnitude of polarization in the ferroelectric layer 120.

For example, when the first polarization control layer 110 includes an N-type material and the second polarization control layer 121 includes a P-type material, the direction of the interface dipole formed between the first polarization control layer 110 and the ferroelectric layer 120 may be directed from the first polarization control layer 110 toward the inside of the ferroelectric layer 120, and the direction of the interface dipole formed between the second polarization control layer 121 and the ferroelectric layer 120 may be directed from the ferroelectric layer 120 toward the inside of the second polarization control layer 121. That is, the direction of the interface dipole between the first polarization control layer 110 and the ferroelectric layer 120 may be the same as the direction of the interface dipole between the second polarization control layer 121 and the ferroelectric layer 120.

In one embodiment, the built-in potential formed in the ferroelectric layer 120 may be greater than the built-in potential formed in the ferroelectric layer 120 of the semiconductor device described with reference to FIGS. 1 and 2. In other words, as the interface dipoles are formed in the same direction at both interfaces of the ferroelectric layer 120, the built-in potential within the ferroelectric layer 120 may be greater than that in a case where an interface dipole is formed only at one side of the ferroelectric layer 120. Accordingly, the polarization behavior of the ferroelectric layer 120 may be shifted further to the right relative to the second polarization behavior 202 described with reference to FIG. 2.

Alternatively, for example, when the first polarization control layer 110 includes a P-type material and the second polarization control layer 121 includes an N-type material, the direction of the interface dipole between the first polarization control layer 110 and the ferroelectric layer 120 may be from the ferroelectric layer 120 toward the inside of the first polarization control layer 110, and the direction of the interface dipole between the second polarization control layer 121 and the ferroelectric layer 120 may be from the second polarization control layer 121 toward the inside of the ferroelectric layer 120. That is, the direction of the interface dipole between the first polarization control layer 110 and the ferroelectric layer 120 may be the same as the direction of the interface dipole between the second polarization control layer 121 and the ferroelectric layer 120.

In one embodiment, the built-in potential formed in the ferroelectric layer 120 may be greater than the built-in potential formed in the ferroelectric layer 120 of the semiconductor device described with reference to FIGS. 3 and 4. That is, as interface dipoles are formed in the same direction at both interfaces of the ferroelectric layer 120, the built-in potential formed within the ferroelectric layer 120 may be greater than in a case where an interface dipole is formed at only one interface of the ferroelectric layer 120. Accordingly, the polarization behavior of the ferroelectric layer 120 may be shifted further to the left relative to the third polarization behavior 402 described with reference to FIG. 4.

In contrast, when both the first and second polarization control layers 110 and 121 include the same type of material (i.e., both N-type or both P-type), the polarization behavior of the ferroelectric layer 120 may be substantially the same as the first polarization behavior 201 described with reference to FIGS. 2 or 4 .

When both the first and second polarization control layers 110 and 121 include either N-type or P-type materials, the direction of the interface dipole between the first polarization control layer 110 and the ferroelectric layer 120 may be opposite to that of the interface dipole between the second polarization control layer 121 and the ferroelectric layer 120. Accordingly, since the interface dipoles at both interfaces cancel each other out, the graph representing the polarization behavior of the ferroelectric layer 120 may be substantially the same as the first polarization behavior 201.

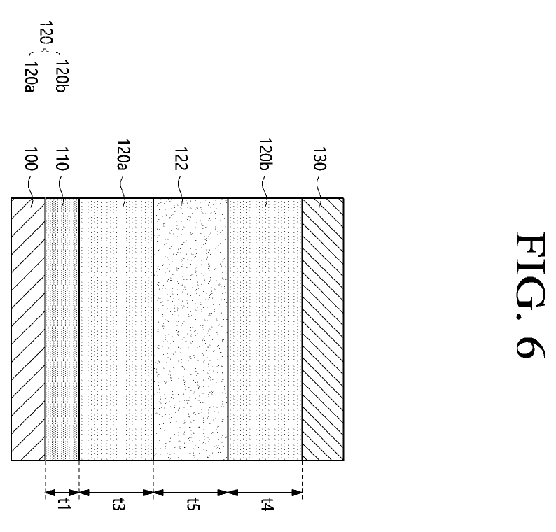

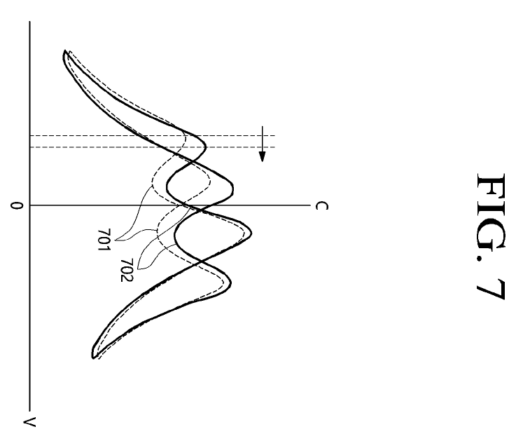

FIG. 6 is a diagram illustrating another example of a cross-sectional structure of a semiconductor device according to embodiments of the present disclosure. FIG. 7 is a diagram schematically illustrating polarization behavior of the semiconductor device shown in FIG. 6.

Referring to FIG. 6, the semiconductor device includes a first electrode 100, a first polarization control layer 110, a first ferroelectric layer 120a, a domain separation layer 122, a second ferroelectric layer 120b, and a second electrode 130. The first ferroelectric layer 120a and the second ferroelectric layer 120b may together form a single ferroelectric layer 120. The first electrode 100, first polarization control layer 110, and second electrode 130 may be substantially the same as those described with reference to FIG. 1.

The first ferroelectric layer 120a is disposed on the first polarization control layer 110. The first ferroelectric layer 120a may include a material having ferroelectricity. For example, the first ferroelectric layer 120a may include hafnium oxide, hafnium-zirconium oxide, or a combination thereof.

A domain separation layer 122 is disposed on the first ferroelectric layer 120a. In one embodiment, the domain separation layer 122 may serve to separate the domains of the first ferroelectric layer 120a and the second ferroelectric layer 120b. A domain may refer to a region within the first or second ferroelectric layer in which the direction of spontaneous electric polarization is uniform. The domains included in the first ferroelectric layer 120a may be different from those included in the second ferroelectric layer 120b due to the presence of the domain separation layer 122. In other words, the direction of spontaneous polarization in the domains of the first ferroelectric layer 120a may be different from that in the second ferroelectric layer 120b. That is, the domains of the first ferroelectric layer 120a may be decoupled from those of the second ferroelectric layer 120b.

The domain separation layer 122 may include a material having a crystal structure similar to that of the first and second ferroelectric layers 120a and 120b. In one embodiment, the domain separation layer 122 may include an oxide having a fluorite structure. For example, the domain separation layer 122 may include zirconium oxide, cerium oxide, or a combination thereof. In one embodiment, the domain separation layer 122 may have a tetragonal or cubic crystal structure.

In one embodiment, the domain separation layer 122 may further include a dopant. The dopant introduced into the domain separation layer 122 may serve to stabilize the crystal structure of the domain separation layer 122.

A dopant doped into the domain separation layer 122 may include metal cations having a valency different from that of the metal element contained in the domain separation layer 122. In one embodiment, the dopant doped into the domain separation layer 122 may include metal cations having a lower valency than that of the metal element contained in the domain separation layer 122. For example, when the domain separation layer 122 includes zirconium oxide, the dopant doped into the domain separation layer 122 may include metal cations having a valency lower than 4, which is the valency of zirconium. Examples include aluminum (Al), yttrium (Y), lanthanum (La), tantalum (Ta), or a combination thereof. In one embodiment, the doping concentration of the dopant in the domain separation layer 122 may range from 0% to 20%.

In one embodiment, the domain separation layer 122 may be non-ferroelectric. For example, the domain separation layer 122 may exhibit paraelectricity.

As the thickness of the domain separation layer 122 increases, the domains in the first and second ferroelectric layers 120a and 120b may be more effectively separated. In addition, the lower the dielectric constant of the material included in the domain separation layer 122, the better the separation between the domains of the first and second ferroelectric layers 120a and 120b may be.

In one embodiment, the thickness t5 of the domain separation layer 122 may account for 5% to 50% of the sum of the thicknesses of the first ferroelectric layer 120a (t3), the domain separation layer 122 (t5), and the second ferroelectric layer 120b (t4). In another embodiment, the thickness t5 of the domain separation layer 122 may range from 10 angstroms to 17 angstroms. If the thickness t5 of the domain separation layer 122 is too small, the distance between the first ferroelectric layer 120a and the second ferroelectric layer 120b may become too short, and as a result, the domains of the first ferroelectric layer 120a and the second ferroelectric layer 120b may not be separated. Accordingly, the thickness t5 should be at least 10 angstroms. In addition, if the thickness t5 of the domain separation layer 122 is too large, the dielectric constant of the semiconductor device may become undesirably low, since the domain separation layer 122 has a relatively lower dielectric constant compared to the first ferroelectric layer 120a and the second ferroelectric layer 120b. Accordingly, the thickness t5 should not exceed 17 angstroms.

A second ferroelectric layer 120b is disposed on the domain separation layer 122. In one embodiment, the second ferroelectric layer 120b may include the same material as the first ferroelectric layer 120a.

As described above, the domains in the second ferroelectric layer 120b may differ from those in the first ferroelectric layer 120a. Accordingly, the voltage required to reverse the polarization direction of the second ferroelectric layer 120b may differ from that required to reverse the polarization direction of the first ferroelectric layer 120a.

In one embodiment, the thickness t4 of the second ferroelectric layer 120b may be substantially the same as the thickness t3 of the first ferroelectric layer 120a. However, this is not limiting, and in some cases, t3 of the first ferroelectric layer 120a and t4 the second ferroelectric layer 120b may be different.

In one embodiment, the ratio among the thicknesses of the first ferroelectric layer 120a (t3), the domain separation layer 122 (t5), and the second ferroelectric layer 120b (t4) may be approximately 1:1:1. In one embodiment, the sum of the thicknesses of the first ferroelectric layer 120a (t3), the second ferroelectric layer 120b (t4), and the domain separation layer 122 (t5) may range from 30 angstroms to 50 angstroms.

FIG. 7 is a diagram illustrating the polarization behavior of the ferroelectric layer 120 when the first polarization control layer 110 includes an N-type material.

Referring to FIG. 7, the first polarization control layer 110 may form an interface dipole between the first ferroelectric layer 120a and the first electrode, and generate a built-in potential within the first ferroelectric layer 120a. Accordingly, the polarization behavior 702 (hereinafter, fifth polarization behavior) of the ferroelectric layer 120, when the first polarization control layer 110 including an N-type material is disposed between the first electrode 100 and the first ferroelectric layer 120a, may differ from the polarization behavior 701 (hereinafter, fourth polarization behavior) of the ferroelectric layer 120 when the first polarization control layer 110 is not present.

In one embodiment, at least a portion of the fifth polarization behavior 702 may be shifted to the right relative to the fourth polarization behavior 701. Since the domain separation layer 122 separates the domains of the second ferroelectric layer 120b from those of the first ferroelectric layer 120a, the polarization behavior of the first ferroelectric layer 120a may be independent of that of the second ferroelectric layer 120b. For example, when the external voltage V applied to the ferroelectric layer 120 is less than 0 (V < 0), the fifth polarization behavior 702 may be shifted to the right relative to the fourth polarization behavior 701. When an external voltage V applied to the ferroelectric layer 120 is greater than 0 (V > 0), the fifth polarization behavior 702 may not be shifted to the left or right. In one embodiment, when an external voltage V applied to the ferroelectric layer 120 is less than 0 (V < 0), the fifth polarization behavior 702 may correspond to the polarization behavior of the first ferroelectric layer 120a. Similarly, when the external voltage V applied to the ferroelectric layer 120 is greater than 0 (V > 0), the fifth polarization behavior 702 may correspond to the polarization behavior of the second ferroelectric layer 120b.

Alternatively, when the first polarization control layer 110 includes a P-type material, at least a portion of the polarization behavior of the ferroelectric layer 120 may be shifted to the left relative to the fourth polarization behavior 701.

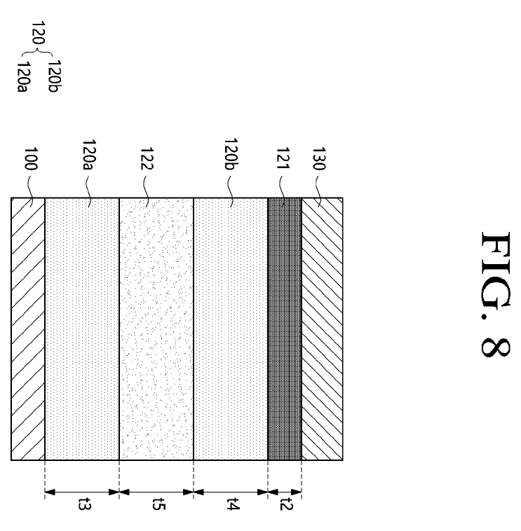

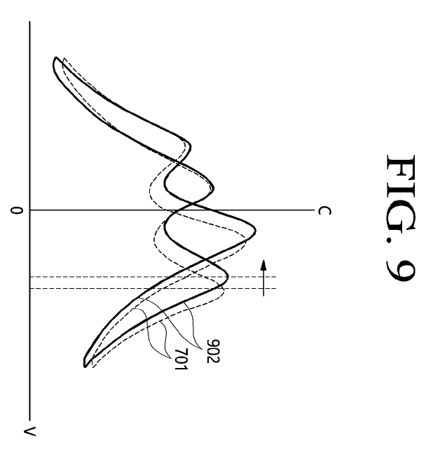

FIG. 8 is a diagram illustrating another example of a cross-sectional structure of a semiconductor device according to embodiments of the present disclosure. FIG. 9 is a diagram schematically illustrating the polarization behavior of the semiconductor device shown in FIG. 8.

Referring to FIG. 8, the semiconductor device includes a first electrode 100, a first ferroelectric layer 120a, a domain separation layer 122, a second ferroelectric layer 120b, a second polarization control layer 121, and a second electrode 130. The first and second ferroelectric layers 120a and 120b may together form a single ferroelectric layer 120. The first electrode 100, second polarization control layer 121, and second electrode 130 may be substantially the same as those described with reference to FIG. 1. The first and second ferroelectric layers 120a and 120b may also be substantially the same as those described with reference to FIG. 6.

FIG. 9 is a diagram illustrating the polarization behavior of the ferroelectric layer 120 when the second polarization control layer 121 includes an N-type material.

Referring to FIGS. 8 and 9, the second polarization control layer 121 may form an interface dipole between the second ferroelectric layer 120b and the second electrode, and generate a built-in potential within the second ferroelectric layer 120b. Accordingly, the polarization behavior 902 (hereinafter, sixth polarization behavior) of the ferroelectric layer 120, when the second polarization control layer 121 including an N-type material is disposed between the second electrode 130 and the second ferroelectric layer 120b, may differ from the fourth polarization behavior 701. In one embodiment, at least a portion of the sixth polarization behavior 902 may be shifted to the left relative to the fourth polarization behavior 701. For example, when the external voltage V applied to the ferroelectric layer 120 is greater than 0 (V > 0), the sixth polarization behavior 902 may be shifted to the left relative to the fourth polarization behavior 701. When an external voltage V applied to the ferroelectric layer 120 is less than 0 (V < 0), the sixth polarization behavior 902 may not be shifted to the left or right. In one embodiment, when the external voltage V applied to the ferroelectric layer 120 is less than 0 (V < 0), the sixth polarization behavior 902 may correspond to the polarization behavior of the first ferroelectric layer 120a. Similarly, when the external voltage V applied to the ferroelectric layer 120 is greater than 0 (V > 0), the sixth polarization behavior 902 may correspond to the polarization behavior of the second ferroelectric layer 120b.

Alternatively, when the second polarization control layer 121 includes a P-type material, at least a portion of the polarization behavior of the ferroelectric layer 120 may be shifted to the right relative to the fourth polarization behavior 701.

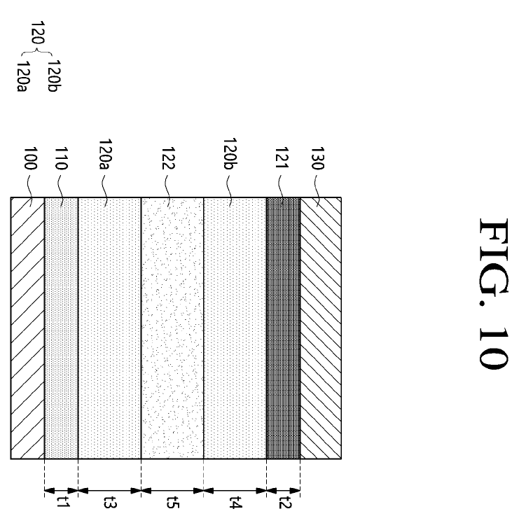

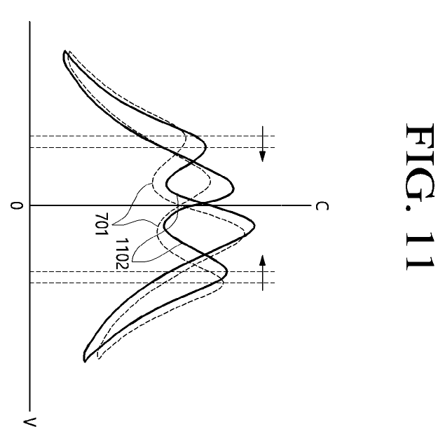

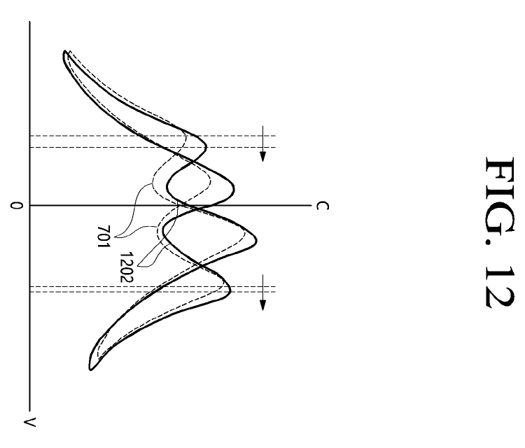

FIG. 10 is a diagram illustrating another example of a cross-sectional structure of a semiconductor device according to embodiments of the present disclosure. FIGS. 11 and 12 are diagrams schematically illustrating the polarization behavior of the semiconductor device shown in FIG. 10.

Referring to FIG. 10, the semiconductor device includes a first electrode 100, a first polarization control layer 110, a first ferroelectric layer 120a, a domain separation layer 122, a second ferroelectric layer 120b, a second polarization control layer 121, and a second electrode 130. The first and second ferroelectric layers band 120b may together form a single ferroelectric layer 120. The first electrode 100, first polarization control layer 110, second polarization control layer 121, and second electrode 130 may be substantially the same as those described with reference to FIG. 1. The first and second ferroelectric layers 120a and 120b may be substantially the same as those described with reference to FIG. 6.

FIG. 11 illustrates the polarization behavior of the ferroelectric layer 120 when both the first and second polarization control layers 110 and 121 include N-type materials.

Referring to FIGS. 10 and 11, the first polarization control layer 110 may form an interface dipole between the first ferroelectric layer 120a and the first electrode, and may generate a built-in potential within the first ferroelectric layer 120a. Accordingly, the polarization behavior 1102 (hereinafter, seventh polarization behavior) of the ferroelectric layer 120 when the first polarization control layer 110 including an N-type material is disposed between the first electrode 100 and the first ferroelectric layer 120a may be different from the fourth polarization behavior 701.

In one embodiment, at least a portion of the seventh polarization behavior 1102 may be shifted to the right relative to the fourth polarization behavior 701, and at least another portion may be shifted to the left relative to the fourth polarization behavior 701. Since the domain separation layer 122 separates the domains of the second ferroelectric layer 120b from those of the first ferroelectric layer 120a, the polarization behavior of the first ferroelectric layer 120a may be independent of that of the second ferroelectric layer 120b. For example, when the external voltage V applied to the ferroelectric layer 120 is less than 0 (V < 0), the seventh polarization behavior 1102 may be shifted to the right relative to the fourth polarization behavior 701. When the external voltage V applied to the ferroelectric layer 120 is greater than 0 (V > 0), the seventh polarization behavior 1102 may be shifted to the left relative to the fourth polarization behavior 701. In one embodiment, when the external voltage V applied to the ferroelectric layer 120 is less than 0, the seventh polarization behavior 1102 may correspond to the polarization behavior of the first ferroelectric layer 120a. Similarly, when the external voltage V applied to the ferroelectric layer 120 is greater than 0, the seventh polarization behavior 1102 may correspond to the polarization behavior of the second ferroelectric layer 120b.

Alternatively, when both the first polarization control layer 110 and the second polarization control layer 121 include P-type materials, at least a portion of the polarization behavior of the ferroelectric layer 120 may be shifted to the left relative to the fourth polarization behavior 701, and at least another portion of the ferroelectric layer 120 may be shifted to the right relative to the fourth polarization behavior 701.

Since the polarization behaviors of the first and second ferroelectric layers 120a and 120b can be independently controlled by the domain separation layer 122, even when both the first and second polarization control layers 110 and 121 include either N-type or P-type materials, the polarization behaviors of the first and second ferroelectric layers 120a and 120b may be shifted independently.

FIG. 12 is a diagram illustrating the polarization behavior of the ferroelectric layer 120 when the first polarization control layer 110 includes an N-type material and the second polarization control layer 121 includes a P-type material.

Referring to FIGS. 10 and 12, the polarization behavior 1202 (hereinafter, eighth polarization behavior) of the ferroelectric layer 120 when the first polarization control layer 110 including an N-type material is disposed between the first electrode 100 and the first ferroelectric layer 120a may be different from the fourth polarization behavior 701. In one embodiment, at least a portion of the eighth polarization behavior 1202 may be shifted to the right relative to the fourth polarization behavior 701. For example, when the external voltage V applied to the ferroelectric layer 120 is less than 0 (V<0), the eighth polarization behavior 1202 may be shifted to the right relative to the fourth polarization behavior 701. Even when the external voltage V applied to the ferroelectric layer 120 is greater than 0 (V>0), the eighth polarization behavior 1202 may still be shifted to the right relative to the fourth polarization behavior 701. In one embodiment, when the external voltage V applied to the ferroelectric layer 120 is less than 0 (V<0), the eighth polarization behavior 1202 may correspond to the polarization behavior of the first ferroelectric layer 120a. Similarly, when the external voltage V applied to the ferroelectric layer 120 is greater than 0 (V>0), the eighth polarization behavior 1202 may correspond to the polarization behavior of the second ferroelectric layer 120b.

Alternatively, when the first polarization control layer 110 includes a P-type material and the second polarization control layer 121 includes an N-type material, at least a portion of the polarization behavior of the ferroelectric layer 120 may be shifted to the left relative to the fourth polarization behavior 701.

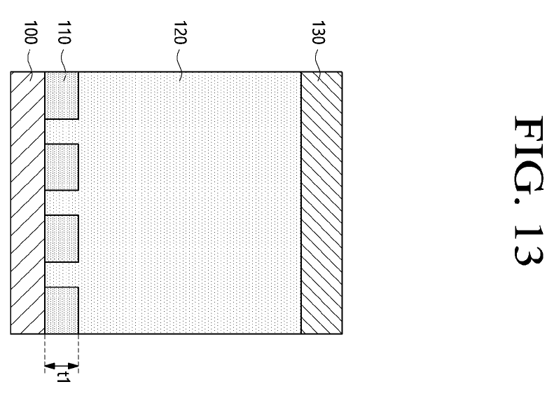

FIG. 13 is a diagram illustrating another example of a cross-sectional structure of a semiconductor device according to embodiments of the present disclosure.

Referring to FIG. 13, the first polarization control layer 110 may be in the form of a plurality of spaced-apart islands. In one embodiment, the ferroelectric layer 120 may fill the spaces between the first polarization control layers 110. In one embodiment, the thickness t1 of the first polarization control layer 110 may range from 1 angstrom to 5 angstroms. Although only the first polarization control layer 110 is shown in the form of spaced-apart islands in FIG. 13, this is not limiting. That is, the second polarization control layer 121 may also be arranged in the form of spaced-apart islands, and each of the first and second polarization control layers 110 and 121 may be arranged as a plurality of spaced-apart islands, respectively.

According to embodiments of the present disclosure, the polarization behavior of the ferroelectric layer 120 may be controlled by disposing the first and second polarization control layers 110 and 121 on the surface of the ferroelectric layer 120. The polarization behavior of the ferroelectric layer 120 may be controlled by selecting the material included in the first or second polarization control layer 110 or 121 according to the desired device characteristics.

In particular, when the semiconductor device further includes the domain separation layer 122, the polarization behaviors of the separated first and second ferroelectric layers 120a and 120b may be independently controlled, allowing for more efficient control of the polarization behavior of the ferroelectric layer 120.

In particular, when the first polarization control layer 110 and the second polarization control layer 121 are disposed between a dielectric layer of a DRAM (Dynamic Random Access Memory) capacitor and an upper electrode, or between the dielectric layer capacitor of the DRAM capacitor and a lower electrode, degradation of device characteristics caused by repeated switching operations may be prevented. For example, when both the first polarization control layer and the second polarization control layer include P-type materials, the polarization behavior of the ferroelectric layer located near the upper electrode may shift to the right, and the polarization behavior of the ferroelectric layer located near the lower electrode may shift to the left. In this case, the voltage required to reverse the polarization of the dielectric layer may increase. Accordingly, even when an abnormally high voltage is applied to the DRAM or repeated switching operations are performed, issues such as polarization behavior reversal may be avoided, thereby preventing degradation of the device characteristics.

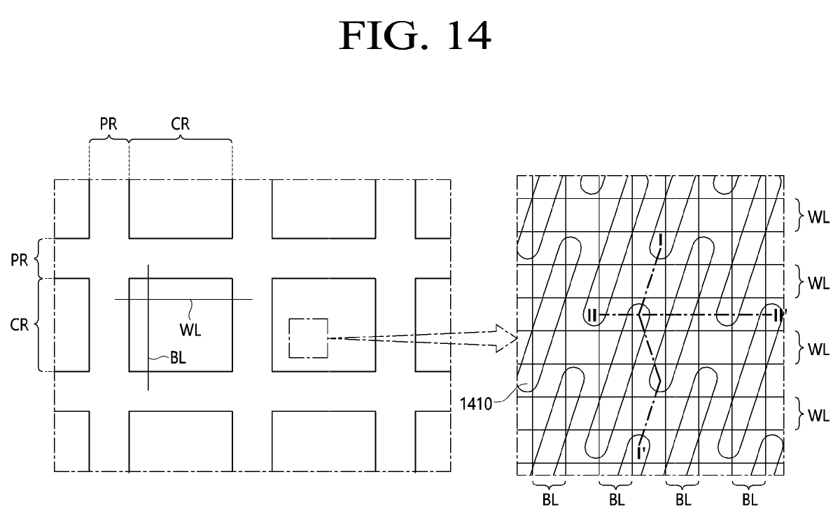

FIG. 14 is a diagram illustrating an example of a planar structure of a semiconductor device according to embodiments of the present disclosure.

The semiconductor device shown in FIG. 14 illustrates an example of the semiconductor device described with reference to FIG. 1, and the semiconductor device according to embodiments of the present disclosure is not limited thereto.

Referring to FIG. 14, the semiconductor device includes a cell region CR and a peripheral region PR. The cell region CR is an area in which memory cells are arranged. The peripheral region PR is an area in which peripheral circuits for delivering various voltages or signals to the memory cells in the cell region CR are arranged. The peripheral region PR is arranged around the cell region CR. In one embodiment, the peripheral region PR may surround the cell region CR.

The semiconductor device includes bit lines BL, word lines WL, and active regions 1410. The active regions 1410 are spaced apart from each other. The bit lines BL and word lines WL are arranged to cross the active regions 1410. In one embodiment, one bit line BL may cross one active region 1410. In another embodiment, two word lines WL may cross one active region 1410. The bit lines BL and word lines WL are arranged to overlap the cell region CR and may extend into the peripheral region PR.

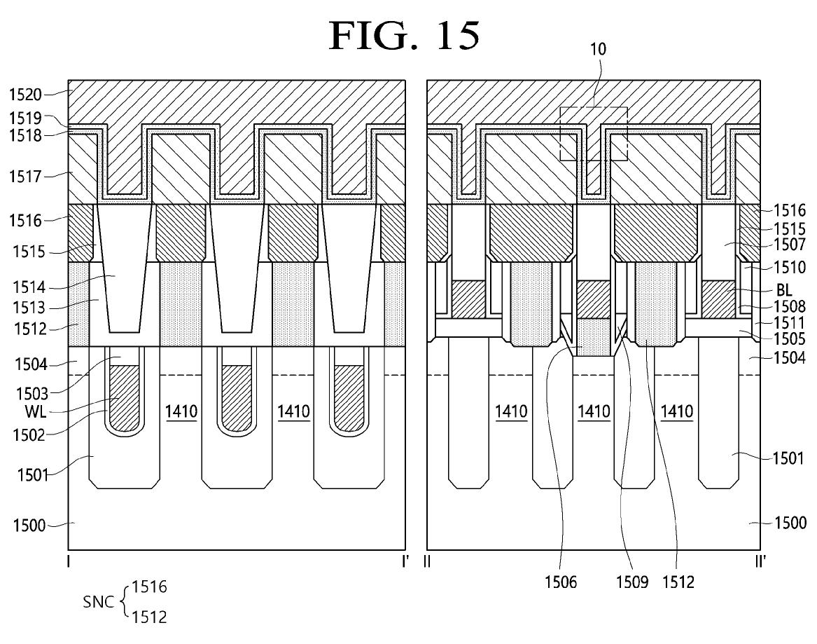

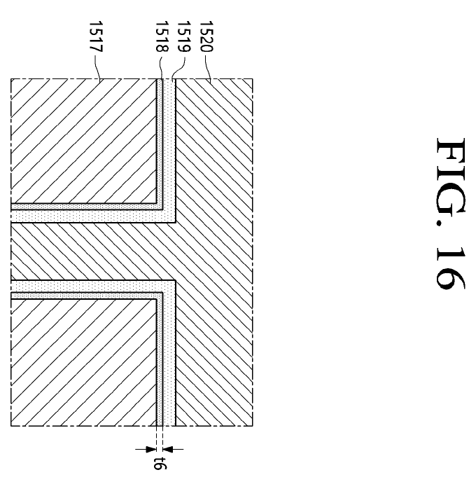

FIG. 15 is a diagram illustrating cross-sectional views taken along lines I–I′ and II–II′ of FIG. 14. FIG. 16 is an enlarged view of a portion labeled 10 in FIG. 15.

Referring to FIGS. 15 and 16, the semiconductor device may include: a substrate 1500, an active region 1410, a device isolation layer 1501, a gate insulating layer 1502, word lines WL, a gate capping layer 1503, source/drain regions 1504, an interlayer insulating layer 1505, a bit line contact 1506, a bit line BL, a bit line capping layer 1507, a first spacer 1508, a gap-fill spacer 1509, a second spacer 1510, a third spacer 1511, a lower contact plug 1512, a first insulating layer 1513, a second insulating layer 1514, an upper spacer 1515, an upper contact plug 1516, a lower electrode 1517, a first polarization control layer 1518, a ferroelectric layer 1519, and an upper electrode 1520.

The lower contact plug 1512 and the upper contact plug 1516 may together form a lower electrode contact plug, SNC.

The substrate 1500 may include a semiconductor substrate such as a silicon wafer or a silicon-on-insulator (SOI) wafer. The substrate 1500 may include a group III-V semiconductor substrate, for example, a compound semiconductor substrate such as GaAs. The substrate 1500 may include single-crystal silicon, polysilicon, amorphous silicon, monocrystalline silicon-germanium, polycrystalline silicon-germanium, carbon-doped silicon, or a combination thereof.

A device isolation layer 1501 that defines an active region 1410 may be disposed in the substrate 1500. The device isolation layer 1501 may be formed using a trench isolation technique such as shallow trench isolation (STI). The device isolation layer 1501 may include silicon oxide, silicon nitride, silicon oxynitride, low-k dielectric materials, high-k dielectric materials, or combinations thereof.

A gate insulating layer 1502 may be disposed within the device isolation layer 1501. A word line WL may be disposed on the inner surface of the gate insulating layer 1502. A gate capping layer 1503 may be disposed on the word line WL. The gate insulating layer 1502 may surround the side and bottom surfaces of the word line WL. The top surface of the word line WL may be located below the top surface of the active region 1410. A source/drain region 1504 may be disposed in the active region 1410 adjacent to the word line WL.

The gate insulating layer 1502 may include silicon oxide, silicon nitride, silicon oxynitride, high-k dielectric materials, or combinations thereof. The word line WL may include a conductive material such as metal, metal oxide, metal nitride, metal silicide, polysilicon, conductive carbon, or a combination thereof. The gate capping layer 1503 may include silicon oxide, silicon nitride, silicon oxynitride, low-k dielectric materials, high-k dielectric materials, or a combination thereof.

An interlayer insulating layer 1505 may be disposed on the device isolation layer 1501, the gate capping layer 1503, and the source/drain region 1504. A bit line contact 1506 may pass through the interlayer insulating layer 1505 and contact the source/drain region 1504. Each of the active regions 1410 may be electrically connected to at least one bit line contact 1506 through a corresponding one of the source/drain regions 1504. The interlayer insulating layer 1505 may include silicon oxide, silicon nitride, silicon oxynitride, low-k dielectric materials, high-k dielectric materials, or combinations thereof.

A bit line BL is disposed on the interlayer insulating layer 1505. The bit line BL may be in contact with at least one bit line contact 1506. A bit line capping layer 1507 may cover the bit line BL. The bit line BL and the bit line contact 1506 may include a conductive material such as metal, metal oxide, metal nitride, metal silicide, polysilicon, conductive carbon, or a combination thereof. The bit line capping layer 1507 may include a dielectric material such as silicon oxide, silicon nitride, silicon oxynitride, low-k dielectric materials, high-k dielectric materials, or a combination thereof.

A first spacer 1508 may be disposed on the side surfaces of the bit line BL and the bit line capping layer 1507 and may extend onto the side surfaces of the bit line contact 1506 and the interlayer insulating layer 1505. A gap-fill spacer 1509 may be disposed on the first spacer 1508 adjacent to the side surfaces of the bit line contact 1506. The first spacer 1508 may extend between the gap-fill spacer 1509 and the device isolation layer 1501.

A second spacer 1510 may be disposed on the first spacer 1508. The side surfaces of the second spacer 1510 may contact the side surfaces of the first spacer 1508. The bottom surface of the second spacer 1510 may contact the first spacer 1508.

A third spacer 1511 may be disposed on the second spacer 1510. The side surfaces of the third spacer 1511 may contact the side surfaces of the second spacer 1510. The third spacer 1511 may extend through the interlayer insulating layer 1505 into the source/drain region 1504. The side surfaces of the third spacer 1511 may contact the first spacer 1508 and the interlayer insulating layer 1505. A lowermost end of the third spacer 1511 may be positioned lower than an uppermost end of the source/drain region 1504.

The first spacer 1508, the second spacer 1510, and the third spacer 1511 may each include a dielectric material such as silicon oxide, silicon nitride, silicon oxynitride, low-k dielectric materials, high-k dielectric materials, or combinations thereof.

Each of the lower contact plugs 1512 may contact a corresponding one of the source/drain regions 1504 in the active region 1410. The upper contact plug 1516 may contact the lower contact plug 1512. At least a portion of the lower contact plug 1512 may overlap an upper portion of a corresponding one of the active regions 1410. The horizontal width of the upper contact plug 1516 may be greater than that of the lower contact plug 1512.

The lower contact plug 1512 and the upper contact plug 1516 may include a conductive material such as metal, metal oxide, metal nitride, metal silicide, polysilicon, conductive carbon, or a combination thereof.

A lowermost end of the lower contact plug 1512 may be positioned at a height lower than an uppermost end of the source/drain region 1504. The lowermost end of the lower contact plug 1512 may also be positioned lower than a lowermost end of the third spacer 1511. An uppermost end of the lower contact plug 1512 may be positioned higher than upper surfaces of adjacent bit lines BL in a vertical direction that spans from the bottom of the substrate 1500 to the upper surface of the upper electrode 1520.

The second insulating layer 1514 may be disposed between the lower electrode contact plugs SNC. The first insulating layer 1513 may surround the side surfaces and the lower surfaces of the second insulating layer 1514. The uppermost end of the first insulating layer 1513 may be positioned lower (in the vertical direction that spans from the bottom of the substrate 1500 to the upper surface of the upper electrode 1520) than the upper surfaces of the second insulating layer 1514. An upper spacer 1515 may be disposed on the first insulating layer 1513 and may surround the side surfaces of the second insulating layer 1514. The upper spacer 1515 may be positioned between the second insulating layer 1514 and the upper contact plug 1516. The upper spacer 1515 may extend between the bit line capping layer 1507 and the upper contact plug 1516.

The second insulating layer 1514 may include silicon oxide, silicon nitride, silicon oxynitride, low-k dielectric materials, high-k dielectric materials, or combinations thereof.

A lower electrode 1517 may be disposed on the lower electrode contact plug SNC. In one embodiment, the lower electrode 1517 may be referred to as a storage node. The storage node may be connected to the lower electrode contact plug SNC. The storage node may have a pillar shape, cylinder shape, box shape, or a combination thereof.

A first polarization control layer 1518 is disposed on the lower electrode 1517. The first polarization control layer 1518 may cover the top and side surfaces of the lower electrode 1517 and the top surface of the second insulating layer 1514. In one embodiment, the thickness t6 of the first polarization control layer 1518 may be in a range from 1 angstrom to 5 angstroms. A ferroelectric layer 1519 is disposed on the first polarization control layer 1518. The first polarization control layer 1518 and the ferroelectric layer 1519 may be the same as the first polarization control layer 110 and the ferroelectric layer 120 described with reference to FIG. 1, respectively.

The first polarization control layer 1518 may include a material having an oxygen area density different from that of the ferroelectric layer 1519.

In one embodiment, the first polarization control layer 1518 may include magnesium oxide, silicon oxide, germanium oxide, yttrium oxide, lutetium oxide, lanthanum oxide, strontium oxide, niobium oxide, or a combination thereof.

Alternatively, in another embodiment, the first polarization control layer 1518 may include titanium oxide, aluminum oxide, or a combination thereof.

In one embodiment, the thickness t1 of the first polarization control layer 1518 may be in a range from 1 angstrom to 5 angstroms. Since the thickness t1 of the first polarization control layer 1518 cannot be less than that of a monolayer, it must be at least 1 angstrom. In addition, if the thickness t1 of the first polarization control layer 1518 exceeds 5 angstroms, the dielectric constant of the semiconductor device may decrease. Accordingly, the thickness t1 of the first polarization control layer 1518 should be less than 5 angstroms.

In one embodiment, the first polarization control layer 1518 may control the direction and magnitude of polarization of the ferroelectric layer 1519. The greater the difference in oxygen area density between the material included in the first polarization control layer 1518 and that of the ferroelectric layer 1519, the greater the change in the direction and magnitude of polarization of the ferroelectric layer 1519 may be.

An upper electrode 1520 is disposed on the ferroelectric layer 1519. The lower electrode 1517, the first polarization control layer 1518, the ferroelectric layer 1519, and the upper electrode 1520 may form a capacitor.

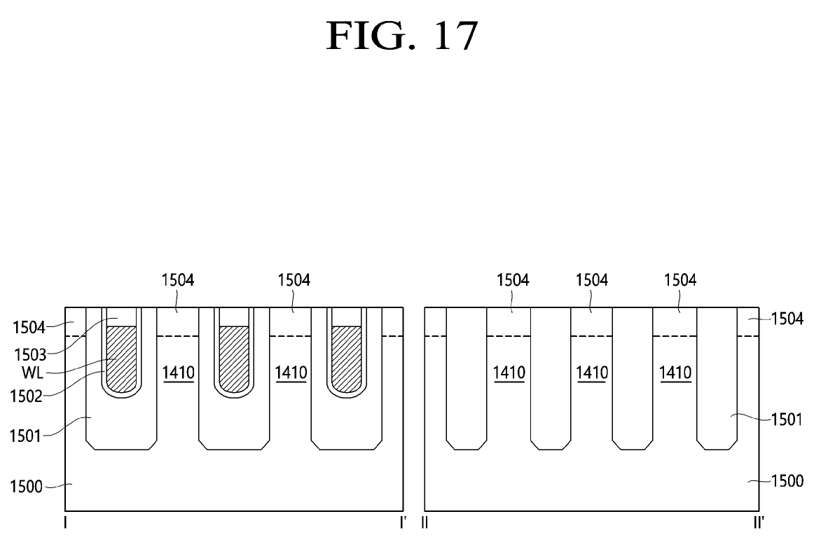

FIGS. 17 through 23 illustrate examples of a method for manufacturing a semiconductor device according to embodiments of the present disclosure.

Referring to FIG. 17, a device isolation layer 1501 defining an active region 1410 is formed in a substrate 1500. There may be multiple device isolation layers 1501, each defining an active region 1410. A gate insulating layer 1502, a word line WL, and a gate capping layer 1503 are sequentially formed within the device isolation layer 1501. The active region 1410 may include monocrystalline silicon doped with P-type impurities. The P-type impurities may include B, BF, BF₂, or combinations thereof.

A source/drain region 1504 is formed in the active region 1410 between the device isolation layers 1501. The source/drain region 1504 may include monocrystalline silicon doped with N-type impurities. The N-type impurities may include P, As, or combinations thereof.

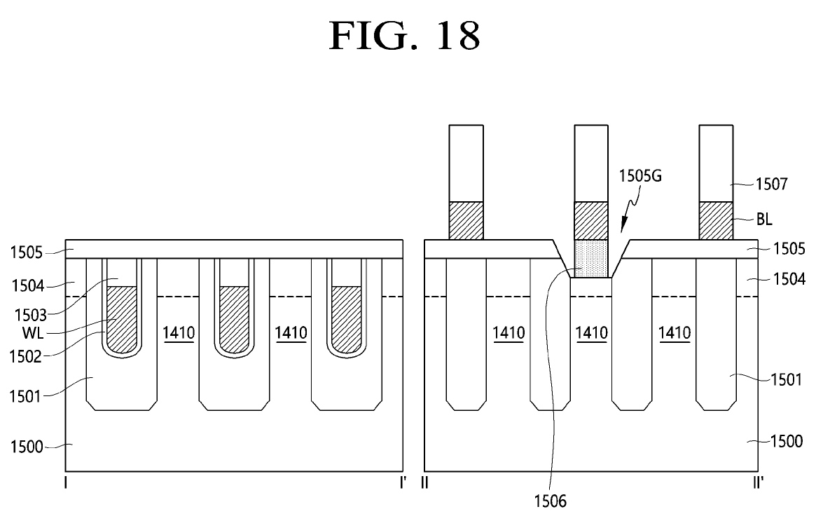

Referring to FIG. 18, an interlayer insulating layer 1505 may be formed to cover the device isolation layer 1501, the gate insulating layer 1502, the gate capping layer 1503, and the source/drain region 1504. A first contact hole 1505G is formed through the interlayer insulating layer 1505 to expose a corresponding one of the source/drain regions 1504. A bit line contact 1506 is formed in the first contact hole 1505G and is connected to the corresponding source/drain region 1504. A bit line BL and a bit line capping layer 1507 are sequentially formed on the bit line contact 1506 and the interlayer insulating layer 1505.

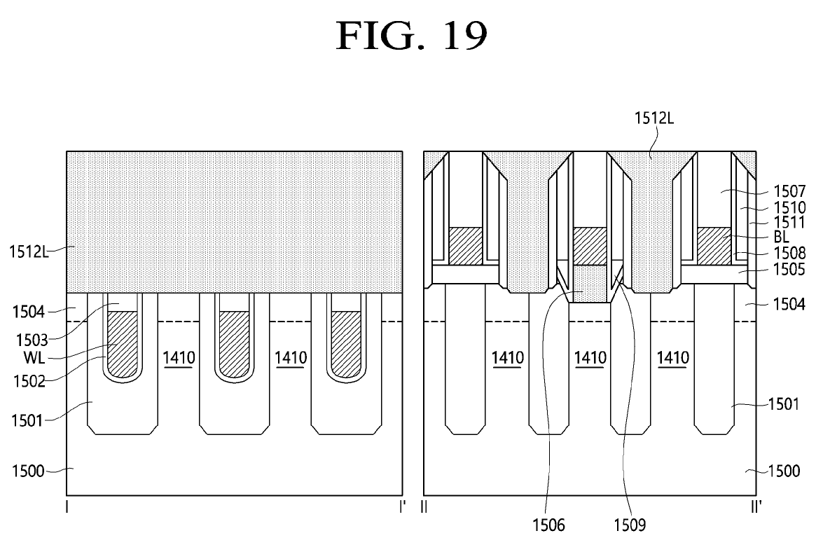

Referring to FIG. 19, a first spacer 1508 is formed on the interlayer insulating layer 1505, the bit line contact 1506, the bit line BL, and the bit line capping layer 1507. A gap-fill spacer 1509 is formed in the region between the bit line contact 1506 and the interlayer insulating layer 1505, and between the bit line contact 1506 and the device isolation layer 1501. The process of forming the gap-fill spacer 1509 may include an etch-back process.

A second spacer 1510 is formed on the first spacer 1508. The second spacer 1510 is formed on the side surfaces of the bit line BL and the bit line capping layer 1507, and on the top surface of the gap-fill spacer 1509. During the formation of the second spacer 1510, a portion of the interlayer insulating layer 1505 may be removed, exposing the source/drain region 1504 and the device isolation layer 1501.

A third spacer 1511 is formed on the side surfaces of the second spacer 1510 and the interlayer insulating layer 1505. The process of forming the third spacer 1511 may include an anisotropic etching process. During the formation of the third spacer 1511, the top surfaces of the source/drain region 1504 and the device isolation layer 1501 may be etched and recessed downward.

A lower contact layer 1512L is formed on the outer surfaces of the source/drain region 1504, the device isolation layer 1501, and the third spacer 1511. The lower contact layer 1512L may be connected to the source/drain region 1504. In one embodiment, the lower contact layer 1512L may include doped polysilicon.

The process of forming the lower contact layer 1512L may include a planarization process. The planarization process for forming the lower contact layer 1512L may include a chemical mechanical polishing (CMP) process, an etch-back process, or a combination thereof. The top surfaces of the lower contact layer 1512L and the bit line capping layer 1507 may be substantially coplanar.

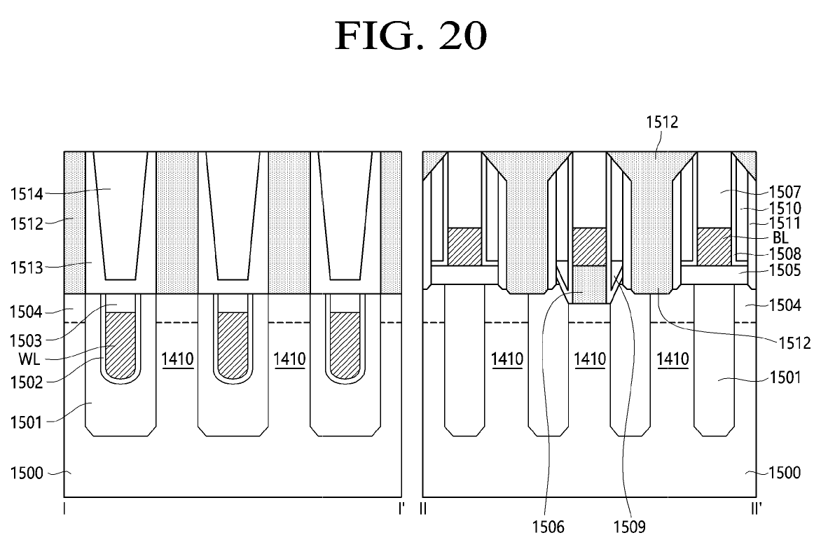

Referring to FIGS. 19 and 20, a portion of the lower contact layer 1512L overlapping the device isolation layer 1501 is partially removed to form the lower contact plug 1512. A first insulating layer 1513 is formed in the region between the lower contact plugs 1512. The first insulating layer 1513 may cover the side surfaces of the lower contact plug 1512 and the top surface of the device isolation layer 1501.

A second insulating layer 1514 is formed on the first insulating layer 1513. A planarization process is then performed such that the top surfaces of the bit line capping layer 1507, the lower contact plug 1512, the first insulating layer 1513, and the second insulating layer 1514 are exposed on the same plane.

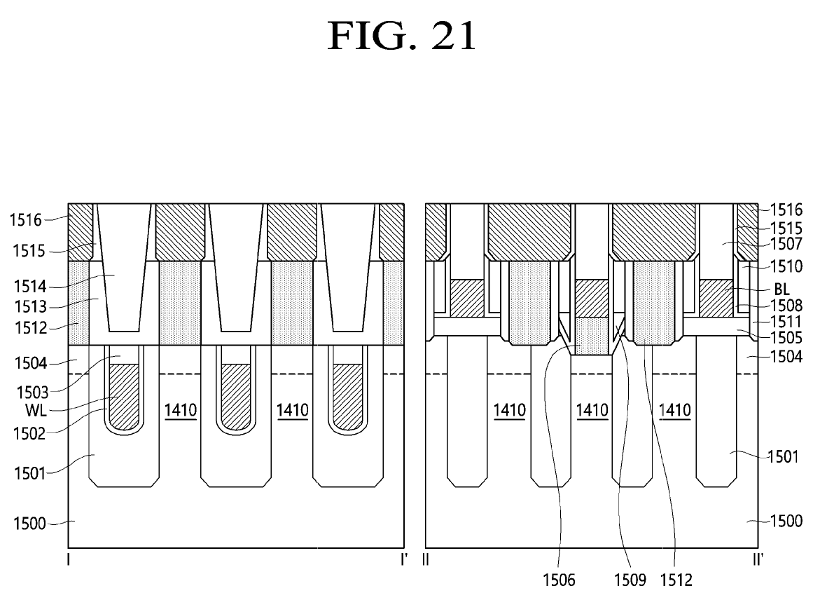

Referring to FIG. 21, at least a portion of the first spacer 1508, the second spacer 1510, the third spacer 1511, the lower contact plug 1512, and the first insulating layer 1513 may be removed. As a result, the top surfaces of the first spacer 1508, the second spacer 1510, the third spacer 1511, the lower contact plug 1512, and the first insulating layer 1513 may be recessed downward.

An upper spacer 1515 and an upper contact plug 1516 are formed in the regions from which the first spacer 1508, the second spacer 1510, the third spacer 1511, the lower contact plug 1512, and the first insulating layer 1513 have been removed. The upper spacer 1515 may contact the top surface of the recessed first insulating layer 1513, the side surfaces of the second insulating layer 1514, and the side surfaces of the bit line capping layer 1507. The upper contact plug 1516 may be connected to the corresponding lower contact plug 1512 and may be in contact with the top surface of the lower contact plug 1512, the top surface of the third spacer 1511, and the side surface of the upper spacer 1515.

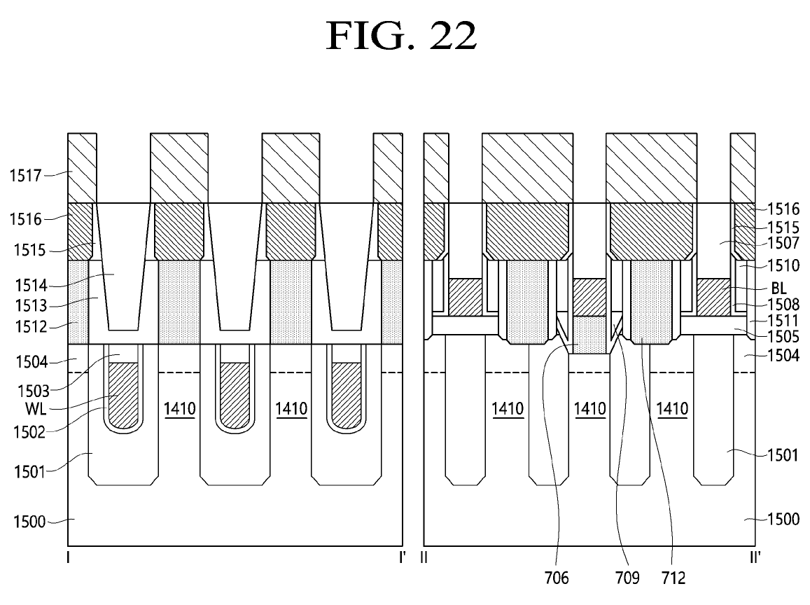

Referring to FIG. 22, a lower electrode 1517 is formed on the upper contact plug 1516. The lower electrode 1517 may be formed on a corresponding upper contact plug 1516. In one embodiment, the lower electrode 1517 may include titanium nitride.

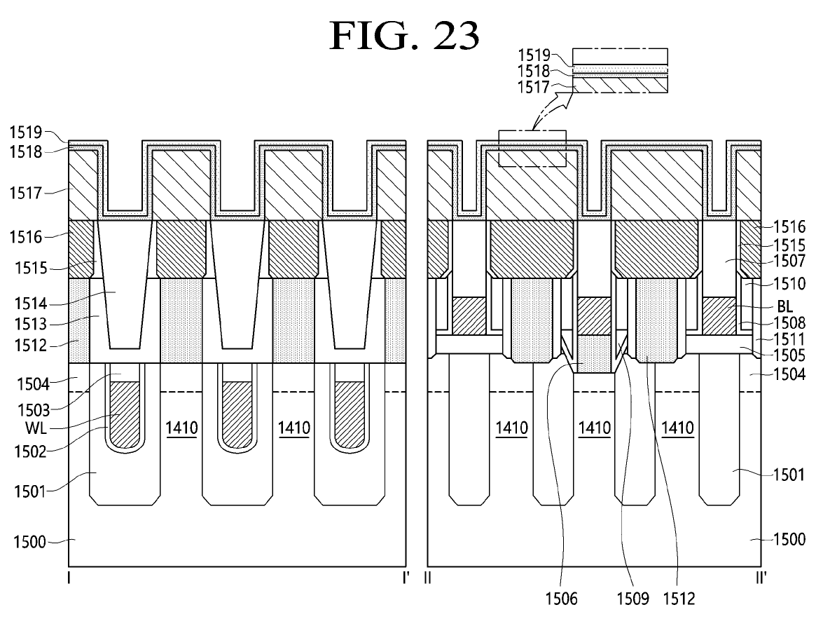

Referring to FIG. 23, a first polarization control layer 1518 is formed on the side and top surfaces of the lower electrode 1517 and on the top surface of the second insulating layer 1514. A ferroelectric layer 1519 is formed on the first polarization control layer 1518. In one embodiment, the first polarization control layer 1518 and the ferroelectric layer 1519 may be formed by an atomic layer deposition process, a pulsed layer deposition process, or a chemical vapor deposition process.

Referring again to FIG. 15, an upper electrode 1520 is formed on the ferroelectric layer 1519. The upper electrode 1520 may cover the top and side surfaces of the ferroelectric layer 1519.

The above description merely provides an illustrative explanation of the present disclosure. Accordingly, a person of ordinary skill in the art to which the present disclosure pertains can make various modifications and variations without departing from the essential characteristics of the present disclosure. In addition, the embodiments disclosed in the present disclosure are not intended to limit the scope of the present disclosure but rather to explain it. Therefore, the scope of the present disclosure should not be limited by the embodiments.

What is claimed is:

1. A semiconductor device comprising:
a first electrode and a second electrode;
a ferroelectric layer disposed between the first electrode and the second electrode;
a first polarization control layer disposed between the first electrode and the ferroelectric layer; and
a second polarization control layer disposed between the second electrode and the ferroelectric layer,
wherein an oxygen area density of the ferroelectric layer is between an oxygen area density of the first polarization control layer and an oxygen area density of the second polarization control layer.

2. The semiconductor device according to claim 1,
wherein the first polarization control layer comprises magnesium oxide, silicon oxide, germanium oxide, yttrium oxide, lutetium oxide, lanthanum oxide, strontium oxide, niobium oxide, or a combination thereof, and
wherein the second polarization control layer comprises titanium oxide, aluminum oxide, or a combination thereof.

3. The semiconductor device according to claim 1,
wherein the first polarization control layer comprises titanium oxide, aluminum oxide, or a combination thereof, and
wherein the second polarization control layer comprises magnesium oxide, silicon oxide, germanium oxide, yttrium oxide, lutetium oxide, lanthanum oxide, strontium oxide, niobium oxide, or a combination thereof.

4. The semiconductor device according to claim 1,
wherein a thickness of each of the first polarization control layer and the second polarization control layer is in a range from 1 angstrom to 5 angstroms.

5. The semiconductor device according to claim 1, wherein at least one of the first polarization control layer and the second polarization control layer has a plurality of spaced-apart island shapes.

6. The semiconductor device according to claim 1,
wherein the ferroelectric layer comprises hafnium oxide, zirconium oxide, or a combination thereof.

7. The semiconductor device according to claim 1, further comprising a domain separation layer having non-ferroelectricity,
wherein the ferroelectric layer comprises a first ferroelectric layer and a second ferroelectric layer which have different domains from each other, and
wherein the domain separation layer is disposed between the first ferroelectric layer and the second ferroelectric layer.

8. The semiconductor device according to claim 7,
wherein the domain separation layer comprises zirconium oxide, cerium oxide, or a combination thereof, and comprises a dopant comprising aluminum (Al), yttrium (Y), lanthanum (La), tantalum (Ta), or a combination thereof.

9. The semiconductor device according to claim 7,
wherein the first polarization control layer comprises magnesium oxide, silicon oxide, germanium oxide, yttrium oxide, lutetium oxide, lanthanum oxide, strontium oxide, niobium oxide, or a combination thereof, and
wherein the second polarization control layer comprises titanium oxide, aluminum oxide, or a combination thereof.

10. The semiconductor device according to claim 7,
wherein each of the first polarization control layer and the second polarization control layer comprises magnesium oxide, silicon oxide, germanium oxide, yttrium oxide, lutetium oxide, lanthanum oxide, strontium oxide, niobium oxide, or a combination thereof.

11. The semiconductor device according to claim 7,
wherein the first polarization control layer comprises titanium oxide, aluminum oxide, or a combination thereof, and
wherein the second polarization control layer comprises magnesium oxide, silicon oxide, germanium oxide, yttrium oxide, lutetium oxide, lanthanum oxide, strontium oxide, niobium oxide, or a combination thereof.

12. The semiconductor device according to claim 7,
wherein each of the first polarization control layer and the second polarization control layer comprises titanium oxide, aluminum oxide, or a combination thereof.

13. The semiconductor device according to claim 7,
wherein at least one of the first polarization control layer and the second polarization control layer has a plurality of spaced-apart island shapes.

14. A semiconductor device comprising:
a first electrode and a second electrode;
a ferroelectric layer disposed between the first electrode and the second electrode, the ferroelectric layer including a first ferroelectric layer and a second ferroelectric layer spaced apart from each other;
a domain separation layer disposed between the first ferroelectric layer and the second ferroelectric layer;
a first polarization control layer disposed between the first electrode and the first ferroelectric layer; and
a second polarization control layer disposed between the second electrode and the second ferroelectric layer,
wherein each of the first polarization control layer and the second polarization control layers has an oxygen area density different from an oxygen area density of the first ferroelectric layer and an oxygen area density of the second ferroelectric layer.

15. The semiconductor device according to claim 14,
wherein the first polarization control layer comprises magnesium oxide, silicon oxide, germanium oxide, yttrium oxide, lutetium oxide, lanthanum oxide, strontium oxide, niobium oxide, or a combination thereof, and
wherein the second polarization control layer comprises titanium oxide, aluminum oxide, or a combination thereof.

16. The semiconductor device according to claim 14,
wherein each of the first polarization control layer and the second polarization control layer comprises magnesium oxide, silicon oxide, germanium oxide, yttrium oxide, lutetium oxide, lanthanum oxide, strontium oxide, niobium oxide, or a combination thereof.

17. The semiconductor device according to claim 14,
wherein the first polarization control layer comprises titanium oxide, aluminum oxide, or a combination thereof, and
wherein the second polarization control layer comprises magnesium oxide, silicon oxide, germanium oxide, yttrium oxide, lutetium oxide, lanthanum oxide, strontium oxide, niobium oxide, or a combination thereof.

18. The semiconductor device according to claim 14,
wherein each of the first polarization control layer and the second polarization control layer comprises titanium oxide, aluminum oxide, or a combination thereof.

19. A semiconductor device comprising:
a substrate including an active region;
a lower electrode contact plug connected to the active region;
a lower electrode connected to the lower electrode contact plug;
an upper electrode disposed over the lower electrode;
a ferroelectric layer disposed between the lower electrode and the upper electrode;
a first polarization control layer disposed between the lower electrode and the ferroelectric layer; and
a second polarization control layer disposed between the upper electrode and the ferroelectric layer,
wherein an oxygen area density of the ferroelectric layer is between an oxygen area density of the first polarization control layer and an oxygen area density of the second polarization control layer.

20. The semiconductor device according to claim 19,
wherein the first polarization control layer comprises magnesium oxide, silicon oxide, germanium oxide, yttrium oxide, lutetium oxide, lanthanum oxide, strontium oxide, niobium oxide, or a combination thereof,
wherein the second polarization control layer comprises titanium oxide, aluminum oxide, or a combination thereof, or the second polarization control layer comprises magnesium oxide, silicon oxide, germanium oxide, yttrium oxide, lutetium oxide, lanthanum oxide, strontium oxide, niobium oxide, or a combination thereof, and
wherein the first polarization control layer comprises titanium oxide, aluminum oxide, or a combination thereof.
